(19) United States
(12) Patent Application Publication
(10) Pub. No.: US 2025/0119138 A1
(43) Pub. Date: Apr. 10, 2025

(54) RECEIVER CIRCUIT, A SEMICONDUCTOR APPARATUS AND A SEMICONDUCTOR SYSTEM INCLUDING THE RECEIVER CIRCUIT

(71) Applicant: SK hynix Inc., Icheon-si Gyeonggi-do (KR)

(72) Inventor: Hyun Su PARK, Icheon-si Gyeonggi-do (KR)

(73) Assignee: SK hynix Inc., Icheon-si Gyeonggi-do (KR)

(21) Appl. No.: 18/437,536

(22) Filed: Feb. 9, 2024

(30) Foreign Application Priority Data
Oct. 4, 2023 (KR) 10-2023-0131774

(51) Int. Cl. H03K 17/56; H03K 3/037; H03L 7/06

(52) U.S. Cl. CPC H03K 17/56; H03K 3/037; H03L 7/06

(57) ABSTRACT

A receiver circuit is configured to generate a reception symbol from a multi-level signal. The receiver circuit is configured to generate three compensation signal pairs from an input signal pair to perform a loop unrolled decision feedback equalization operation. A first summing circuit is configured to equalize the input signal pair with a first offset to generate a first compensation signal pair, and a second summing circuit is configured to equalize the input signal pair with a second offset to generate a second compensation signal pair. An averaging circuit is configured to average the first compensation signal pair and the second compensation signal pair to generate a third compensation signal pair.

### CROSS-REFERENCES TO RELATED APPLICATION

The present application claims priority under 35 U.S.C. § 119 (a) to Korean application number 10-2023-0131774 filed on Oct. 4, 2023, in the Korean Intellectual Property Office, which is incorporated herein by reference in its entirety as set forth in full.

### BACKGROUND

### 1. Technical Field

Various embodiments generally relate to integrated circuit technology, and, more particularly, to a receiver circuit, a semiconductor apparatus and a semiconductor system using the receiver circuit.

### 2. Related Art

An electronic device includes a lot of electronic elements and a computer system as the electronic device includes lots of semiconductor apparatuses each configured by semiconductor devices. Semiconductor apparatus constituting a computer system can communicate with each other by transmitting and receiving a clock signal and data. The semiconductor apparatuses may be coupled to other semiconductor apparatuses through a data bus, and may transmit and receive signals having information corresponding to the data through the data bus. Typically, a Non Return to Zero (NRZ) signal having a logic level of 0 or 1 may be transmitted through the data bus. However, in order to transmit more information with one signal transmission, a multi-level signal transmission method using Pulse Amplitude Modulation (PAM) is being used. The multi-level signal transmission method can transmit two or more bits of digital information as one analog signal by subdividing levels of analog voltages transmitted through the signal bus.

In order to use the multi-level signal transmission method, the semiconductor apparatuses may include a transmitter circuit that encodes a plurality of bits of data to generate a symbol, and transmits a PAM signal having three or more voltage levels based on the symbol to the data bus. Further, the semiconductor apparatuses may include a receiver circuit that receives the PAM signal transmitted through the data bus to restore the symbol, and decodes the symbol to generate the plurality of bits of data.

### SUMMARY

In an embodiment, a receiver circuit may include a first summing circuit, a second summing circuit, an averaging circuit, a sampling circuit, and an output circuit. The first summing circuit may be configured to equalize an input signal pair with a first offset to generate a first compensation signal pair. The second summing circuit may be configured to equalize the input signal pair with a second offset to generate a second compensation signal pair. The averaging circuit may be configured to average voltage levels of the first compensation signal pair and the second compensation signal pair to generate a third compensation signal pair. The sampling circuit may be configured to compare the first compensation signal pair, the second compensation signal pair, and the third compensation signal pair with a first reference voltage and a second reference voltage to generate a first sampling signal pair, a second sampling signal pair, and a third sampling signal pair, respectively. The output circuit may be configured to generate an nth reception symbol from one sampling signal pair among the first to third sampling signal pairs based on an n-1th reception symbol, wherein the n is an integer of 2 or more.

In an embodiment, a semiconductor apparatus may include a first receiver circuit and a second receiver circuit. The first receiver circuit may be configured to receive an input signal pair, and may be configured to generate a first reception symbol from the input signal pair in synchronization with a first phase clock signal. The second receiver circuit may be configured to receive the input signal pair, and may be configured to generate a second reception symbol from the input signal pair in synchronization with a second phase clock signal. The first receiver circuit may include a compensation signal generation circuit, a sampling circuit, and an output circuit. The compensation signal generation circuit may be configured to equalize the input signal pair with a first offset to generate a first compensation signal pair, may be configured to equalize the input signal pair with a second offset to generate a second compensation signal pair, and may be configured to average voltage levels of the first compensation signal pair and the second compensation signal pair to generate a third compensation signal pair. The sampling circuit may be configured to compare the first compensation signal pair, the second compensation signal pair, and the third compensation signal pair with a first reference voltage and a second reference voltage to generate a first sampling signal pair, a second sampling signal pair, and a third sampling signal pair, respectively in synchronization with the first phase clock signal. The output circuit may be configured to select one sampling signal pair among the first to third sampling signal pairs based on the second reception symbol to generate a selected sampling signal pair, and may be configured to generate the selected sampling signal pair as the first reception symbol in synchronization with the first phase clock signal.

### BRIEF DESCRIPTION OF THE DRAWINGS

FIG. 1 is a diagram illustrating a configuration of a semiconductor system and a voltage level of a multi-level signal transmitted through a transmission signal bus according to an embodiment.

FIG. 2 is a diagram illustrating a configuration of a receiver circuit according to an embodiment.

FIG. 3 is a diagram illustrating changes in voltage levels of various signal pairs shown in FIG. 2.

FIG. 4 is a diagram illustrating a configuration of a first summing circuit illustrated in FIG. 2.

FIG. 5 is a diagram illustrating a configuration of a first sense amplifier shown in FIG. 2.

FIG. 6 is a diagram illustrating a configuration of a first amplification circuit shown in FIG. 5.

FIG. 7 is a block diagram illustrating a configuration of a multiplexer shown in FIG. 2.

FIG. 8 is a diagram illustrating a configuration of a first selection circuit shown in FIG. 7.

FIG. 9 is a table illustrating an operation of a receiver circuit according to an embodiment.

FIG. 10 is a diagram illustrating a configuration of a semiconductor apparatus according to an embodiment.

FIG. 11 is a diagram illustrating a configuration of a semiconductor apparatus according to an embodiment.

### DETAILED DESCRIPTION

It will be understood that although the terms “first,” “second,” “third,” etc. are used herein to describe various elements, these elements should not be limited by these terms. These terms are only used to distinguish one element from another element and are not intended to imply an order or number of elements. Thus, a first element in some embodiments could be termed a second element in other embodiments without departing from the teachings of the present disclosure.

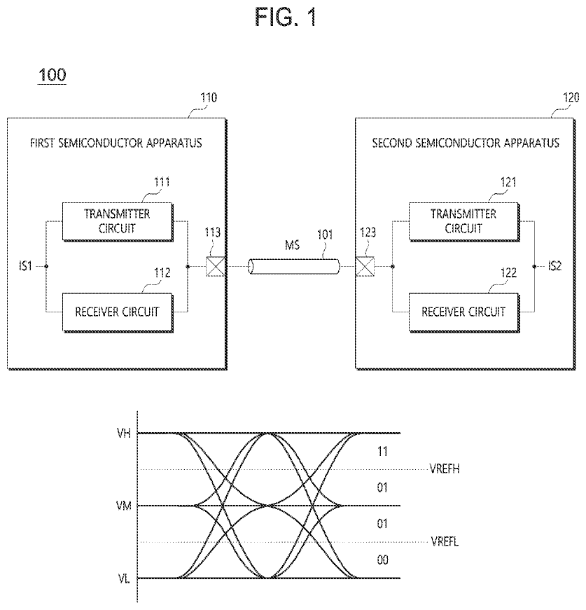

FIG. 1 is a diagram illustrating a configuration of a semiconductor system 100 and a voltage level of a multi-level signal MS transmitted through a transmission signal bus 101 according to an embodiment of the present disclosure. Referring to FIG. 1, the semiconductor system 100 may include a first semiconductor apparatus 110 and a second semiconductor apparatus 120. The first semiconductor apparatus 110 may be a master apparatus that provides various control signals required for the second semiconductor apparatus 120 to operate. The first semiconductor apparatus 110 may include various types of host devices. For example, the first semiconductor apparatus 110 may include at least one of a central processing unit (CPU), a graphic processing unit (GPU), a multi-media processor (MMP), a digital signal processor (DSP), an application processor (AP), and a memory controller. The second semiconductor apparatus 120 may be a slave apparatus capable of receiving the control signals from the first semiconductor apparatus 110 to perform various operations. For example, the second semiconductor apparatus 120 may be a memory apparatus, and the memory apparatus may include volatile memory and non-volatile memory. The volatile memory may include SRAM (Static RAM), DRAM (Dynamic RAM), SDRAM (Synchronous DRAM), and the non-volatile memory may include ROM (Read Only Memory), PROM (Programmable ROM), EEPROM (Electrically Erasable and Programmable ROM), EPROM (Erasable and Programmable ROM), flash memory, PRAM (Phase change RAM), MRAM (Magnetic RAM), RRAM (Resistive RAM), and FRAM (Ferroelectric RAM).

The second semiconductor apparatus 120 may be coupled to the first semiconductor apparatus 110 through a plurality of buses. The plurality of buses may be signal transmission lines, links, or channels for transmitting signals. Although not shown, for example, the plurality of buses may include a clock bus, a command address bus, and a data bus. The clock bus and the command address bus may be unidirectional buses from the first semiconductor apparatus 110 to the second semiconductor apparatus 120, and the data bus may be bidirectional bus. The second semiconductor apparatus 120 may be coupled to the first semiconductor apparatus 110 through a transmission signal bus 101. The transmission signal bus 101 may include any kind of bus that transmits signal synchronized to a clock signal. For example, the transmission signal bus 101 may be a bidirectional bus, such as the data bus. In an embodiment, the transmission signal bus 101 may be a unidirectional bus, and technical ideas of the present disclosure may be similarly applicable in case that the transmission signal bus 101 is a unidirectional bus. The transmission signal bus 101 may be a multi-level signal transmission line transmitting the multi-level signal MS. For example, the multi-level signal MS may have at least three different voltage levels, and the multi-level signal MS may have a voltage level of one of the three different voltage levels according to a value of a symbol. The symbol may include at least two binary bits. The symbol may have at least a first state, a second state, and a third state. The first state may be a high state, and the symbol representing the first state may have a logic value of ‘1, 1’. The second state may be a middle state, and the symbol representing the second state may have a logic value of ‘0, 1’. The third state is a low state, and the symbol representing the third state may have a logic value of ‘0, 0’. The multi-level signal MS may have a first voltage level VH, a second voltage level VM, and a third voltage level VL.

A graph shown in FIG. 1 is a diagram illustrating a voltage level of the multi-level signal MS transmitted through the transmission signal bus 101. To transmit a symbol of the first state, the multi-level signal MS may have the first voltage level VH. To transmit a symbol of the second state, the multi-level signal MS may have the second voltage level VM. To transmit a symbol of the third state, the multi-level signal MS may have the third voltage level VL. The second voltage level VM may be lower than the first voltage level VH, and the third voltage level VL may be lower than the second voltage level VM. The multi-level signal MS may be maintained at current voltage level or may be changed to the other two voltage levels according to whether a state of the symbol transitions. For example, when the symbol transitions from the second state to the third state, the multi-level signal MS may change from the second voltage level VM to the third voltage level VL. A voltage level of the multi-level signal MS and a state of the symbol may be determined using at least two reference voltages. The at least two reference voltages may include a first reference voltage VREFH and a second reference voltage VREFL. The first reference voltage VREFH may have a voltage level corresponding to substantially a middle between the first voltage level VH and the second voltage level VM. The second reference voltage VREFL may have a voltage level corresponding to substantially a middle between the second voltage level VM and the third voltage level VL. When the multi-level signal MS has a voltage level higher than the first reference voltage VREFH, the multi-level signal MS may be determined to represent a symbol of the first state. When the multi-level signal MS has a voltage level lower than the first reference voltage VREFH and higher than the second reference voltage VREFL, the multi-level signal MS may be determined to represent a symbol of the second state. When the multi-level signal MS has a voltage level lower than the second reference voltage VREFL, the multi-level signal MS may be determined to represent a symbol of the third state.

The first semiconductor apparatus 110 may include a transmitter circuit 111 and a receiver circuit 112. The transmitter circuit 111 and the receiver circuit 112 may be coupled with the transmission signal bus 101 through a pad 113. The transmitter circuit 111 may receive an internal signal IS1 of the first semiconductor apparatus 110, and transmit the multi-level signal MS generated based on the internal signal IS1 to the second semiconductor apparatus 120 through the pad 113 and the transmission signal bus 101. The receiver circuit 112 may receive the multi-level signal MS transmitted through the transmission signal bus 101 and the pad 113, and may generate the internal signal IS1 based on the multi-level signal MS. For example, the transmitter circuit 111 may generate the multi-level signal MS having a voltage level corresponding to one of the first to third voltages VH, VM, VL according to a state of a symbol generated based on a bit stream of the internal signal IS1. The transmitter circuit 111 may encode the bit stream of the internal signal IS1, which is a digital signal, to generate the symbol, and may convert the symbol into the multi-level signal MS, which is an analog voltage. The receiver circuit 112 may detect a voltage level of the multi-level signal MS to restore the symbol, and may decode the symbol to generate the bit stream of the internal signal IS1.

The second semiconductor apparatus 120 may include a transmitter circuit 121 and a receiver circuit 122. The transmitter circuit 121 and the receiver circuit 122 may be coupled with the transmission signal bus 101 through a pad 123. The transmitter circuit 121 may receive an internal signal IS2 of the second semiconductor apparatus 120, and transmit the multi-level signal MS generated based on the internal signal IS2 to the first semiconductor apparatus 110 through the pad 123 and the transmission signal bus 101. The receiver circuit 122 may receive the multi-level signal MS transmitted through the transmission signal bus 101 and the pad 123, and may generate the internal signal IS2 based on the multi-level signal MS. For example, the transmitter circuit 121 may generate the multi-level signal MS having a voltage level corresponding to one of the first to third voltages VH, VM, VL according to a state of a symbol generated based on a bit stream of the internal signal IS2. The transmitter circuit 121 may encode the bit stream of the internal signal IS2, which is a digital signal, to generate the symbol, and may convert the symbol into the multi-level signal MS, which is an analog voltage. The receiver circuit 122 may detect a voltage level of the multi-level signal MS to restore the symbol, and may decode the symbol to generate the bit stream of the internal signal IS2.

When a voltage level of the multi-level signal MS transitions, inter-symbol interference (ISI) may occur in the multi-level signal MS. The inter-symbol interference may cause distortion of the multi-level signal MS, which may reduce communication reliability between the first and second semiconductor apparatuses 110, 120. In an embodiment, to compensate for the inter-symbol interference, the receiver circuits 112, 122 may include a decision feedback equalizer (DFE). The decision feedback equalizer may equalize a voltage level of a currently received multi-level signal MS based on a symbol generated from a previously received multi-level signal MS. In an embodiment, the decision feedback equalizer may remove or compensate one or more post cursor components generated by the previously received multi-level signal MS to ensure integrity of the currently received multi-level signal MS.

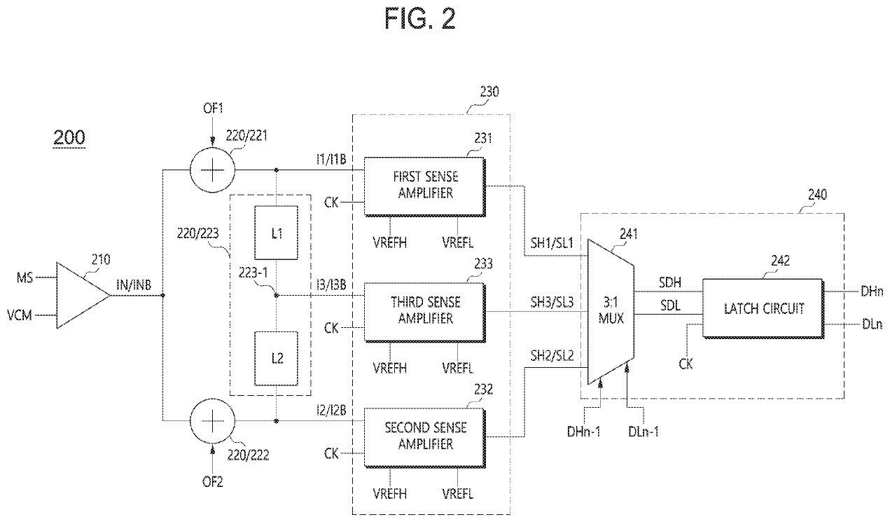

FIG. 2 is a diagram illustrating a configuration of a receiver circuit 200 according to an embodiment. Referring to FIG. 2, the receiver circuit 200 may receive the multi-level signal MS and generate reception symbol DH, DL. The receiver circuit 200 may perform a decision feedback equalization operation on the multi-level signal MS to generate the reception symbol DH, DL. The receiver circuit 200 may perform a loop unrolled decision feedback equalization operation suitable for receiving the multi-level signal MS transmitted at a high frequency. The receiver circuit 200 may include a buffer circuit 210, a compensation signal generation circuit 220, a sampling circuit 230, and an output circuit 240. The buffer circuit 210 may receive the multi-level signal MS. The multi-level signal MS may be a signal input to the receiver circuit 112 or the receiver circuit 122 through the transmission signal bus 101 shown in FIG. 1. The multi-level signal MS may be a single-ended signal. The buffer circuit 210 may convert the multi-level signal MS into differential signals. The buffer circuit 210 may receive the multi-level signal MS and a common mode voltage VCM, and may differentially amplify the multi-level signal MS and the common mode voltage VCM to generate an input signal pair IN/INB. The input signal pair IN/INB may include an input signal IN and a complementary input signal INB. The input signal IN may have a voltage level corresponding to the multi-level signal MS, and the complementary input signal INB may have a voltage level opposite to the input signal IN. The buffer circuit 210 may include any kind of differential amplifier, and may include a Continuous Time Linear Equalizer (CTLE).

The compensation signal generation circuit 220 may receive the input signal pair IN/INB, and may generate a first compensation signal pair I1/I1B, a second compensation signal pair I2/I2B, and a third compensation signal pair I3/I3B by changing voltage levels of the input signal pair IN/INB. The first compensation signal pair I1/I1B may include a first compensation signal I1 and a first complementary compensation signal I1B. The second compensation signal pair I2/I2B may include a second compensation signal I2 and a second complementary compensation signal I2B. The third compensation signal pair I3/I3B may include a third compensation signal I3 and a third complementary compensation signal I3B. The compensation signal generation circuit 220 may equalize the input signal pair IN/INB with a first offset OF1 to generate the first compensation signal pair I1/I1B. The compensation signal generation circuit 220 may equalize the input signal pair IN/INB with a second offset OF2 to generate the second compensation signal pair I2/I2B. The first offset OF1 may be a positive offset, and the second offset OF2 may be a negative offset. The compensation signal generation circuit 220 may generate the third compensation signal pair I3/I3B by averaging the first compensation signal pair I1/I1B and the second compensation signal pair I2/I2B. The compensation signal generation circuit 220 may include a first summing circuit 221, a second summing circuit 222, and an averaging circuit 223.

The first summing circuit 221 may receive the input signal pair IN/INB, and may generate the first compensation signal pair I1/I1B by changing voltage levels of the input signal pair IN/INB. A voltage level of the first compensation signal I1 may be changed corresponding to a voltage level change of the input signal IN, and a voltage level of the first complementary compensation signal I1B may be changed corresponding to a voltage level change of the complementary input signal INB. The first summing circuit 221 may equalize the input signal pair IN/INB with the first offset OF1 to generate the first complementary compensation signal pair I1/I1B. For example, the first summing circuit 221 may maintain a voltage level of the input signal IN and generate the first compensation signal I1 having a voltage level substantially equal to the voltage level of the input signal IN. The first summing circuit 221 may lower a voltage level of the complementary input signal INB by a voltage level corresponding to the first offset OF1, and output a signal having a lowered voltage level as the first complementary compensation signal I1B. The voltage level corresponding to the first offset OF1 may be arbitrarily decided. The first summing circuit 221 may receive a coefficient signal for setting the first offset OF1, and may change voltage levels of the input signal pair IN/INB based on the coefficient signal to generate the first compensation signal pair I1/I1B.

The second summing circuit 222 may receive the input signal pair IN/INB, and may generate the second compensation signal pair I2/I2B by changing voltage levels of the input signal pair IN/INB. A voltage level of the second compensation signal I2 may be changed corresponding to a voltage level change of the input signal IN, and a voltage level of the second complementary compensation signal I2B may be changed corresponding to a voltage level change of the complementary input signal INB. The second summing circuit 222 may equalize the input signal pair IN/INB with the second offset OF2 to generate the second complementary compensation signal pair I2/I2B. For example, the second summing circuit 222 may lower a voltage level of the input signal IN by a voltage level corresponding to the second offset OF2, and output a signal having a lowered voltage level as the second compensation signal I2. The second summing circuit 222 may maintain a voltage level of the complementary input signal INB and generate the second complementary compensation signal I2B having a voltage level substantially equal to the voltage level of the complementary input signal INB. The voltage level corresponding to the second offset OF2 may be arbitrarily decided.

A voltage level of the complementary input signal INB changed by being equalized with the first offset OF1 and a voltage level of the input signal IN changed by being equalized with the second offset OF2 may be substantially the same. The second summing circuit 222 may receive a coefficient signal for setting the second offset OF2, and may change voltage levels of the input signal pair IN/INB based on the coefficient signal to generate the second compensation signal pair I2/I2B. The coefficient signal received by the second summing circuit 222 may be different from the coefficient signal received by the first summing circuit 221, and the coefficient signal received by the second summing circuit 222 may be complementary to the coefficient signal received by the first summing circuit 221.

The averaging circuit 223 may receive the first compensation signal pair I1/I1B and the second compensation signal pair I2/I2B. The averaging circuit 223 may average the first compensation signal pair I1/I1B and the second compensation signal pair I2/I2B to generate the third compensation signal pair I3/I3B. The averaging circuit 223 may generate the third compensation signal I3 by averaging voltage levels the first compensation signal I1 and the second compensation signal I2. The averaging circuit 223 may generate the third compensation signal I3 having a voltage level corresponding to substantially a middle between the voltage levels of the first compensation signal I1 and the second compensation signal I2. The averaging circuit 223 may generate the third complementary compensation signal I3B by averaging voltage levels the first complementary compensation signal I1B and the second complementary compensation signal I2B. The averaging circuit 223 may generate the third complementary compensation signal I3B having a voltage level corresponding to substantially a middle between the voltage levels of the first complementary compensation signal I1B and the second complementary compensation signal I2B. The receiver circuit 200 and the compensation signal generation circuit 220 may generate the third compensation signal pair I3/I3B by averaging the first compensation signal pair I1/I1B and the second compensation signal pair I2/I2B, without having a separate summing circuit or driver to generate the third compensation signal pair I3/I3B. Thus, in an embodiment, the circuit area and power consumption of the receiver circuit 200 may be reduced.

The averaging circuit 223 may include a first load circuit L1 and a second load circuit L2. One end of the first load circuit L1 may receive the first compensation signal pair I1/I1B, and the other end of the first load circuit L1 may be coupled with a node 223-1 from which the third compensation signal pair I3/I3B is output. One end of the second load circuit L2 may receive the second compensation signal pair I2/I2B, and the other end of the second load circuit L2 may be coupled with the node 223-1 from which the third compensation signal pair I3/I3B is output. An impedance of the first load circuit L1 may be substantially the same as an impedance of the second load circuit L2. In an embodiment, the impedance of the first load circuit L1 may be different from the impedance of the second load circuit L2 to adjust a voltage level difference of the third compensation signal pair I3/I3B. The first and second load circuits L1, L2 may include a resistor element, a capacitor element, and the like.

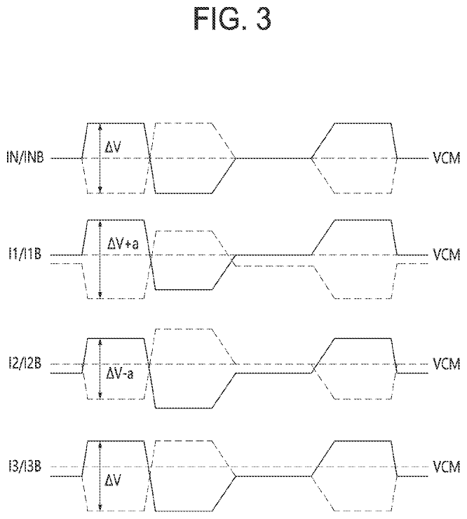

FIG. 3 is a diagram illustrating changes in voltage levels of various signal pairs illustrated in FIG. 2. Referring to FIGS. 2 and 3, a voltage level of the input signal pair IN/INB may move up and down around a voltage level of the common mode voltage VCM. The signals shown in solid lines may be the input signal IN, the first compensation signal I1, the second compensation signal I2, and the third compensation signal I3, and the signals shown in dashed lines may be the complementary input signal INB, the first complementary compensation signal I1B, the second complementary compensation signal I2B, and the third complementary compensation signal I3B. The input signal IN and the complementary input signal INB may have a voltage level difference corresponding to ΔV. The first summing circuit 221 may generate the first compensation signal I1 having a voltage level substantially equal to the input signal IN, and may generate the first complementary compensation signal I1B by lowering a voltage level of the complementary input signal INB. When a voltage level corresponding to the first offset OF1 is “a”, the first compensation signal I1 and the first complementary compensation signal I1B may have a voltage level difference corresponding to ΔV+a. The second summing circuit 222 may lower a voltage level of the input signal IN to generate the second compensation signal I2, and may generate the second complementary compensation signal I2B having a voltage level substantially equal to the complementary input signal INB. Similarly, when a voltage level corresponding to the second offset OF2 is “a”, the second compensation signal I2 and the second complementary compensation signal I2B may have a voltage level difference corresponding to ΔV−a. The averaging circuit 223 may generate the third compensation signal pair I3/I3B by averaging the voltage level of the first compensation signal pair I1/I1B and the voltage level of the second compensation signal pair I2/I2B. Thus, the third compensation signal I3 and the third complementary compensation signal I3B may have a voltage level difference corresponding to ΔV substantially the same as the input signal pair IN/INB.

Referring again to FIG. 2, the sampling circuit 230 may receive the first compensation signal pair I1/I1B, the second compensation signal pair I2/I2B, and the third compensation signal pair I3/I3B. Further, the sampling circuit 230 may receive a first reference voltage VREFH and a second reference voltage VREFL. The first reference voltage VREFH may have a higher voltage level than the second reference voltage VREFL. The first reference voltage VREFH may be substantially the same as the first reference voltage VREFH shown in FIG. 1, and the second reference voltage VREFL may be substantially the same as the second reference voltage VREFL shown in FIG. 1. The sampling circuit 230 may generate a first sampling signal pair SH1, SL1, a second sampling signal pair SH2, SL2, and a third sampling signal pair SH3, SL3, respectively, by comparing the first compensation signal pair I1/I1B, the second compensation signal pair I2/I2B, and the third compensation signal pair I3/I3B with the first reference voltage VREFH and the second reference voltage VREFL. The sampling circuit 230 may generate the first sampling signal pair SH1, SL1 by comparing the first compensation signal pair I1/I1B with the first and second reference voltages VREFH, VREFL. The first sampling signal pair SH1, SL1 may include a first sampling signal SH1 and a second sampling signal SL1. The sampling circuit 230 may generate the second sampling signal pair SH2, SL2 by comparing the second compensation signal pair I2/I2B with the first and second reference voltages VREFH, VREFL. The second sampling signal pair SH2, SL2 may include a third sampling signal SH2 and a fourth sampling signal SL2. The sampling circuit 230 may generate the third sampling signal pair SH3, SL3 by comparing the third compensation signal pair I3/I3B with the first and second reference voltages VREFH, VREFL. The third sampling signal pair SH3, SL3 may include a fifth sampling signal SH3 and a sixth sampling signal SL3. The sampling circuit 230 may further receive a clock signal CK, and may compare the first to third compensation signal pairs I1/I1B, I2/I2B, I3/I3B with the first and second reference voltages VREFH, VREFL in synchronization with the clock signal CK.

The sampling circuit 230 may include a first sense amplifier 231, a second sense amplifier 232, and a third sense amplifier 233. The first sense amplifier 231 may receive the first compensation signal pair I1/I1B, the first reference voltage VREFH, and the second reference voltage VREFL, and may sense and amplify the first compensation signal pair I1/I1B and the first and second reference voltages VREFH, VREFL to generate the first sampling signal pair SH1, SL1. The first sense amplifier 231 may receive the clock signal CK, and may perform a sampling operation in synchronization with the clock signal CK to generate the first sampling signal pair SH1, SL1. The second sense amplifier 232 may receive the second compensation signal pair I2/I2B, the first reference voltage VREFH, and the second reference voltage VREFL, and may sense and amplify the second compensation signal pair I2/I2B and the first and second reference voltages VREFH, VREFL to generate the second sampling signal pair SH2, SL2. The second sense amplifier 232 may receive the clock signal CK, and may perform a sampling operation in synchronization with the clock signal CK to generate the second sampling signal pair SH2, SL2. The third sense amplifier 233 may receive the third compensation signal pair I3/I3B, the first reference voltage VREFH, and the second reference voltage VREFL, and may sense and amplify the third compensation signal pair I3/I3B and the first and second reference voltages VREFH, VREFL to generate the third sampling signal pair SH3, SL3. The third sense amplifier 233 may receive the clock signal CK, and may perform a sampling operation in synchronization with the clock signal CK to generate the third sampling signal pair SH3, SL3.

The output circuit 240 may receive the first sampling signal pair SH1, SL1, the second sampling signal pair SH2, SL2, and the third sampling signal pair SH3, SL3 from the sampling circuit 230 to generate the reception symbol DH, DL. The output circuit 240 may generate an nth reception symbol DHn, DLn from one sampling signal pair among the first sampling signal pair SH1, SL1, the second sampling signal pair SH2, SL2, and the third sampling signal pair SH3, SL3 based on an n-1th reception symbol DHn-1, DLn-1. The output circuit 240 may select one sampling signal pair of the first to third sampling signal pairs SH1, SL1, SH2, SL2, SH3, SL3 based on the previously generated reception symbol DHn-1, DLn-1. The output circuit 240 may select one sampling signal pair among the first to third sampling signal pairs SH1, SL1, SH2, SL2, SH3, SL3 generated from the nth received multi-level signal MS based on the n-1th reception symbol DHn-1, DLn-1 generated from the n-1th received multi-level signal MS to output a selected sampling signal pair SDH, SDL, and may output the selected sampling signal pair SDH, SDL as the nth reception symbol DHn, DLn. Here, n may be an integer of 2 or more. The selected sampling signal pair SDH, SDL may include a first selected sampling signal SDH and a second selected sampling signal SDL. The output circuit 240 may latch the selected sampling signal pair SDH, SDL to generate the nth reception symbol DHn, DLn. The output circuit 240 may receive the clock signal CK. The output circuit 240 may latch the selected sampling signal pair SDH, SDL in synchronization with the clock signal CK. The reception symbol DH, DL may include a most significant bit DH and a least significant bit DL. The output circuit 240 may output one of the first sampling signal SH1, the third sampling signal SH2, and the fifth sampling signal SH3 as the most significant bit DHn of the nth reception symbol based on the n-1th reception symbol DHn-1, DLn-1, and may output a sampling signal paired with the sampling signal output as the most significant bit DHn of the nth reception symbol as the least significant bit DLn of the nth reception symbol. For example, when the most significant bit DHn-1 and the least significant bit DLn-1 of the n-1th reception symbol are both 1, or when the n-1th reception symbol DHn-1, DLn-1 was in the first state, the output circuit 240 may output the third sampling signal SH2 as the most significant bit DHn of the nth reception symbol, and output the fourth sampling signal SL2 as the least significant bit DLn of the nth reception symbol. When the most significant bit DHn-1 of the n-1th reception symbol is 0 and the least significant bit DLn-1 is 1, or when the n-1th reception symbol DHn-1, DLn-1 was in the second state, the output circuit 240 may output the fifth sampling signal SH3 as the most significant bit DHn of the nth reception symbol, and may output the sixth sampling signal SL3 as the least significant bit DLn of the nth reception symbol. When both the most significant bit DHn-1 and the least significant bit DLn-1 of the n-1th reception symbol are zero, or when the n-1th reception symbol DHn-1, DLn-1 was in the third state, the output circuit 240 may output the first sampling signal SH1 as the most significant bit DHn of the nth reception symbol and the second sampling signal SL1 as the least significant bit DLn of the nth reception symbol. In an embodiment, the clock signal received by the output circuit 240 and the clock signal received by the amplification circuit 230 may have different phases. For example, the clock signal received by the output circuit 240 may have a lagged phase relative to a phase of the clock signal received by the amplification circuit 230.

The output circuit 240 may include a multiplexer 241, and a latch circuit 242. In an embodiment, the multiplexer 241 may be a 3:1 multiplexer. The multiplexer 241 may receive the first to third sampling signal pairs SH1, SL1, SH2, SL2, SH3, SL3 and the n-1th reception symbol DHn-1, DLn-1. The multiplexer 241 may select one sampling signal pair among the first to third sampling signal pairs SH1, SL1, SH2, SL2, SH3, SL3 based on the n-1th reception symbol DHn-1, DLn-1 to output the selected sampling signal pair SDH, SDL. The multiplexer 241 may select one sampling signal pair among the first to third sampling signal pairs SH1, SL1, SH2, SL2, SH3, SL3 according to logic levels of the most significant bit DHn-1 and the least significant bit DLn-1 of the n-1th reception symbol. The latch circuit 242 may receive the selected sampling signal pair SDH, SDL. The latch circuit 242 may latch the selected sampling signal pair SDH, SDL to generate the nth reception symbol DHn, DLn. The latch circuit 242 may output the first selected sampling signal SDH as the most significant bit DHn of the nth reception symbol, and may output the second selected sampling signal SDL as the least significant bit DLn of the nth reception symbol. The latch circuit 242 may receive the clock signal CK, and may generate the nth reception symbol DHn, DLn in synchronization with the clock signal CK.

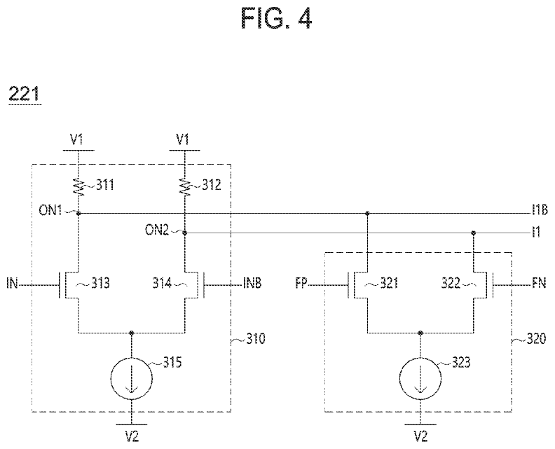

FIG. 4 is a diagram illustrating a configuration of the first summing circuit 221 shown in FIG. 1. Referring to FIG. 4, the first summing circuit 221 may include an amplification circuit 310 and an offset circuit 320. The amplification circuit 310 may receive the input signal IN and the complementary input signal INB. The amplification circuit 310 may differentially amplify the input signal IN and the complementary input signal INB to change voltage levels of the first output node ON1 and the second output node ON2. The first output node ON1 may be a negative output node, and the first complementary compensation signal I1B may be output through the first output node ON1. The second output node ON2 may be a positive output node, and the first compensation signal I1 may be output through the second output node ON2. The amplification circuit 310 may change a voltage level of the first output node ON1 to a voltage level opposite to the input signal IN, and may change a voltage level of the second output node ON2 to a voltage level opposite to the complementary input signal INB.

The offset circuit 320 may receive a first coefficient signal FP and a second coefficient signal FN. The offset circuit 320 may change a voltage level of the first output node ON1 based on the first coefficient signal FP. The offset circuit 320 may decrease a voltage level of the first complementary compensation signal I1B based on the first coefficient signal FP. The offset circuit 320 may change a voltage level of the second output node ON2 based on the second coefficient signal FN. The offset circuit 320 may decrease a voltage level of the first compensation signal I1 based on the second coefficient signal FN. The logic levels of the first coefficient signal FP and the second coefficient signal FN may be changed according to the first offset OF1 set by the first summing circuit 221.

The amplification circuit 310 may include a first resistor 311, a second resistor 312, a first transistor 313, a second transistor 314, and a first current source 315. One end of the first resistor 311 may be coupled with a terminal to which a first power supply voltage V1 is supplied, and the other end of the first resistor 311 may be coupled with the first output node ON1. One end of the second resistor 312 is coupled with the terminal to which the first power supply voltage V1 is supplied, and the other end of the second resistor 312 may be coupled with the second output node ON2. The first transistor 313 and the second transistor 314 may be N-channel MOS transistors. A gate of the first transistor 313 may receive the input signal IN, and a drain of the first transistor 313 may be coupled with the first output node ON1. A gate of the second transistor 314 may receive the complementary input signal INB, and a drain of the second transistor 314 may be coupled with the second output node ON2. One end of the first current source 315 may be in common connection with sources of the first and second transistors 313, 314. The other end of the first current source 315 may be coupled to a terminal to which a second power supply voltage V2 is supplied. The second power supply voltage V2 may have a lower voltage level than the first power supply voltage V1.

The offset circuit 320 may include a third transistor 321, a fourth transistor 322, and a second current source 323. The third and fourth transistors 321, 322 may be N-channel MOS transistors. A gate of the third transistor 321 may receive the first coefficient signal FP, and a drain of the third transistor 321 may be coupled with the first output node ON1. A gate of the fourth transistor 322 may receive the second coefficient signal FN, and a drain of the fourth transistor 322 may be coupled with the second output node ON2. One end of the second current source 323 may be coupled in common with sources of the third and fourth transistors 321, 322, and the other end of the second current source 323 may be coupled with the terminal to which the second power supply voltage V2 is supplied. The offset circuit 320 may determine a voltage level to be lowered by the first summing circuit 221 by adjusting at least one of voltage levels or logic levels of the first coefficient signal FP and the second coefficient signal FN, current driving forces of the third and fourth transistors 321, 322, or an amount of current of the second current source 323. The first coefficient signal FP may have a voltage level corresponding to a high logic level, and the second coefficient signal FN may have a voltage level corresponding to a low logic level. Thus, the offset circuit 320 may maintain a voltage level of the first compensation signal I1 and may decrease a voltage level of the first complementary compensation signal I1B. The second summing circuit 222, shown in FIG. 2, may have substantially the same structure as the first summing circuit 221. A third transistor of the second summing circuit 222 may receive the second coefficient signal FN instead of the first coefficient signal FP, and a fourth transistor of the second summing circuit 222 may receive the first coefficient signal FP instead of the second coefficient signal FN. Thus, the second summing circuit 222 may decrease a voltage level of the second compensation signal I2 and maintain a voltage level of the second complementary compensation signal I2B.

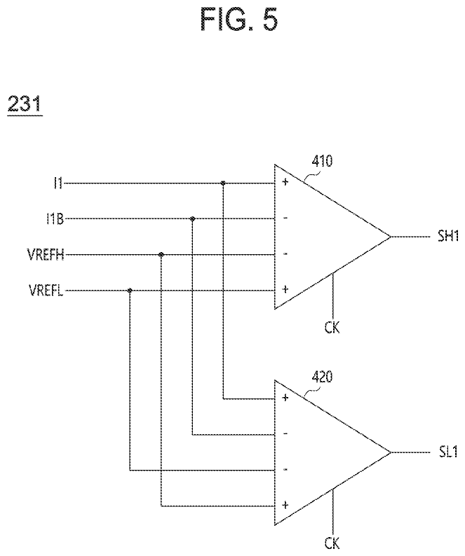

FIG. 5 is a diagram illustrating a configuration of the first sense amplifier 231 shown in FIG. 2. The first sense amplifier 231 may include a first amplification circuit 410 and a second amplification circuit 420. The first amplification circuit 410 may receive the first compensation signal I1, the first complementary compensation signal I1B, the first reference voltage VREFH, and the second reference voltage VREFL, and may generate the first sampling signal SH1 based on the first compensation signal I1, the first complementary compensation signal I1B, the first reference voltage VREFH, and the second reference voltage VREFL. A positive input terminal (+) of the first amplification circuit 410 may receive the first compensation signal I1 and the second reference voltage VREFL, and a negative input terminal (−) of the first amplification circuit 410 may receive the first complementary compensation signal I1B and the first reference voltage VREFH. The first amplification circuit 410 may generate the first sampling signal SH1 by comparing voltage levels of the first compensation signal I1 and the second reference voltage VREFL with voltage levels of the first complementary compensation signal I1B and the first reference voltage VREFH. The first amplification circuit 410 may further receive the clock signal CK, and may perform an amplification operation in synchronization with the clock signal CK.

The second amplification circuit 420 may receive the first compensation signal I1, the first complementary compensation signal I1B, the first reference voltage VREFH, and the second reference voltage VREFL, and may generate the second sampling signal SL1 based on the first compensation signal I1, the first complementary compensation signal I1B, the first reference voltage VREFH, and the second reference voltage VREFL. A positive input terminal (+) of the second amplification circuit 420 may receive the first compensation signal I1 and the first reference voltage VREFH, and a negative input terminal (−) of the second amplification circuit 420 may receive the first complementary compensation signal I1B and the second reference voltage VREFL. The second amplification circuit 420 may generate the second sampling signal SL1 by comparing voltage levels of the first compensation signal I1 and the first reference voltage VREFH with voltage levels of the first complementary compensation signal I1B and the second reference voltage VREFL. The second amplification circuit 420 may further receive the clock signal CK, and may perform an amplification operation in synchronization with the clock signal CK. The second sense amplifier 232 shown in FIG. 2 may have the same configuration as the first sense amplifier 231, except that the first compensation signal pair I1/I1B is replaced by the second compensation signal pair I2/I2B, and the first sampling signal pair SH1, SL1 is replaced by the second sampling signal pair SH2, SL2. The third sense amplifier 233 shown in FIG. 2 may have the same configuration as the first sense amplifier 231, except that the first compensation signal pair I1/I1B is replaced by the third compensation signal pair I3/I3B, and the first sampling signal pair SH1, SL1 is replaced by the third sampling signal pair SH3, SL3.

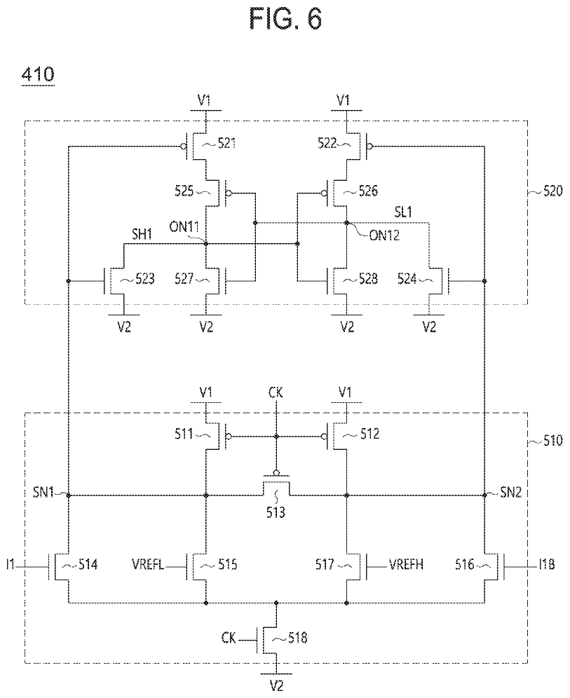

FIG. 6 is a diagram illustrating a configuration of the first amplification circuit 410 shown in FIG. 5. Referring to FIG. 6, the first amplification circuit 410 may include an amplifier 510 and a latch 520. The amplifier 510 may change voltage levels of a first sensing node SN1 and a second sensing node SN2 based on the first compensation signal I1, the first complementary compensation signal I1B, the first reference voltage VREFH, the second reference voltage VREFL, and the clock signal CK. The amplifier 510 may be activated when the clock signal CK is at a high logic level and deactivated when the clock signal CK is at a low logic level. The amplifier 510 may change the voltage level of the first sensing node SN1 based on the first compensation signal I1 and the second reference voltage VREFL, and may change the voltage level of the second sensing node SN2 based on the first complementary compensation signal I1B and the first reference voltage VREFH. The latch 520 may be coupled with the first sensing node SN1 and the second sensing node SN2. The latch 520 may sense voltage levels of the first and second sensing nodes SN1, SN2 to generate the first sampling signal SH1 and the second sampling signal SL1. The latch 520 may change a voltage level of the first output node ON11 according to a voltage level of the first sensing node SN1, and may change a voltage level of the second output node ON12 according to a voltage level of the second sensing node SN2. The latch 520 may latch the voltage levels of the first and second output nodes ON11, ON12 to generate the first sampling signal pair SH1, SL1. The first sampling signal SH1 may be output from the first output node ON11.

The amplifier 510 may include a first transistor 511, a second transistor 512, a third transistor 513, a fourth transistor 514, a fifth transistor 515, a sixth transistor 516, a seventh transistor 517, and an eighth transistor 518. The first to third transistors 511, 512, 513 may precharge the first and second sensing nodes SN1, SN2 with the first power supply voltage V1 based on the clock signal CK. The first to third transistors 511, 512, 513 may function as a precharge circuit. The first to third transistors 511, 512, 513 may be P-channel MOS transistors. A gate of the first transistor 511 may receive the clock signal CK, a source of the first transistor 511 may be coupled with a terminal to which the first power supply voltage V1 is supplied, and a drain of the first transistor 511 may be coupled with the first sensing node SN1. A gate of the second transistor 512 may receive the clock signal CK, a source of the second transistor 512 is coupled with the terminal to which the first supply voltage V1 is supplied, and a drain of the second transistor 512 may be coupled with the second sensing node SN2. The third transistor 513 is coupled between the first and second sensing nodes SN1, SN2, and a gate of the third transistor 513 may receive the clock signal CK.

The fourth to seventh transistors 514, 515, 516, 517 may function as a differential input circuit of the amplifier 510. The fourth and fifth transistors 514, 515 may receive signals input through the positive input terminal of the first amplifier circuit 410, and the sixth and seventh transistors 516, 517 may receive signals input through the negative input terminal of the first amplifier circuit 410. The fourth and fifth transistors 514, 515 may change a voltage level of the first sensing node SN1 based on the first compensation signal I1 and the second reference voltage VREFL, and the sixth and seventh transistors 516, 517 may change a voltage level of the second sensing node SN2 based on the first complementary compensation signal I1B and the first reference voltage VREFH. The fourth to seventh transistors 514, 515, 516, 517 may be N-channel MOS transistors. A gate of the fourth transistor 514 may receive the first compensation signal I1, and a drain of the fourth transistor 514 may be coupled with the first sensing node SN1. A gate of the fifth transistor 515 may receive the second reference voltage VREFL, and a drain of the fifth transistor 515 may be coupled with the first sensing node SN1. A gate of the sixth transistor 516 may receive the first complementary compensation signal I1B, and a drain of the sixth transistor 516 may be coupled with the second sensing node SN2. A gate of the seventh transistor 517 may receive the first reference voltage VREFH, and a drain of the seventh transistor 517 may be coupled with the second sensing node SN2.

The eighth transistor 518 may receive the clock signal CK to form a current path for the amplifier 510 and activate the amplifier 510. The eighth transistor 518 may function as an enable circuit. The eighth transistor 518 may be an N-channel MOS transistor. A gate of the eighth transistor 518 may receive the clock signal CK, a drain of the eighth transistor 518 may be coupled in common with sources of the fourth to seventh transistors 514, 515, 516, 517, and a source of the eighth transistor 518 may be coupled with the terminal to which the second power voltage V2 is supplied.

The latch 520 may include a first transistor 521, a second transistor 522, a third transistor 523, a fourth transistor 524, a fifth transistor 525, a sixth transistor 526, a seventh transistor 527, and an eighth transistor 528. The first transistor 521, the second transistor 522, the fifth transistor 525, and the sixth transistor 526 may be P-channel MOS transistors, and the third transistor 523, the fourth transistor 524, the seventh transistor 527, and the eighth transistor 528 may be N-channel MOS transistors. A gate of the first transistor 521 may be coupled with the first sensing node SN1, and a source of the first transistor 521 may be coupled with the terminal to which the first power supply voltage V1 is supplied. A gate of the second transistor 522 is coupled with the second sensing node SN2, and a source of the second transistor 522 may be coupled with the terminal to which the first power supply voltage V1 is supplied. A gate of the third transistor 523 is coupled with the first sensing node SN1, a drain of the third transistor 523 is coupled with a first output node ON11, and a source of the third transistor 523 may be coupled with the terminal to which the second power supply voltage V2 is supplied. A gate of the fourth transistor 524 is coupled with the second sensing node SN2, a drain of the fourth transistor 524 is coupled with a second output node ON12, and a source of the fourth transistor 524 may be coupled with the terminal to which the second power supply voltage V2 is supplied. A gate of the fifth transistor 525 is coupled with the second output node ON12, a source of the fifth transistor 525 is coupled with the drain of the first transistor 521, and a drain of the fifth transistor 525 may be coupled with the first output node ON11. A gate of the sixth transistor 526 is coupled with the first output node ON11, a source of the sixth transistor 526 is coupled with the drain of the second transistor 522, and a drain of the sixth transistor 526 may be coupled with the second output node ON12. A gate of the seventh transistor 527 is coupled with the second output node ON12, a drain of the seventh transistor 527 is coupled with the first output node ON11, and a source of the seventh transistor 527 may be coupled with the terminal to which the second power supply voltage V2 is supplied. A gate of the eighth transistor 528 is coupled with the first output node ON11, a drain of the eighth transistor 528 is coupled with the second output node ON12, and a source of the eighth transistor 528 may be coupled with the terminal to which the second power supply voltage V2 is supplied.

When the clock signal CK has a low logic level, the first to third transistors 511, 512, 513 may be turned on, and the eighth transistor 518 may be turned off. The first to third transistors 511, 512, 513 may precharge the first and second sensing nodes SN1, SN2 to a voltage level of the first power supply voltage V1. When the clock signal CK has a high logic level, the first to third transistors 511, 512, 513 may be turned off, and the eighth transistor 518 may be turned on to couple the fourth to seventh transistors 514, 515, 516, 517 with the terminal to which the second power supply voltage V2 is supplied. When the amount of current flowing through the fourth to fifth transistors 514, 515 according to voltage levels of the first compensation signal I1 and the second reference voltage VREFL is greater than the amount of current flowing through the sixth to seventh transistors 516, 517 according to voltage levels of the first complementary compensation signal I1B and the first reference voltage VREFH, a voltage level of the first sensing node SN1 may be lower than a voltage level of the second sensing node SN2. The first transistor 521 may be turned on and the third transistor 523 may be turned off, while the second transistor 522 may be turned off and the fourth transistor 524 may be turned on. Thus, the second output node ON12 may change to a low logic level, and the first output node ON11 may change to a high logic level as the fifth transistor 525 is turned on. As the fifth transistor 525 and the eighth transistor 528 are maintained in the turn-on state, the first output node ON11 may be maintained at a high logic level and the second output node ON12 may be maintained at a low logic level, and the first sampling signal SH1 having a high logic level may be output through the first output node ON11.

Conversely, when the amount of current flowing through the fourth to fifth transistors 514, 515 according to voltage levels of the first compensation signal I1 and the second reference voltage VREFL is less than the amount of current flowing through the sixth to seventh transistors 516, 517 according to voltage levels of the first complementary compensation signal I1B and the first reference voltage VREFH, a voltage level of the second sensing node SN2 may be lower than a voltage level of the first sensing node SN1. The first transistor 521 may be turned off and the third transistor 523 may be turned on, while the second transistor 522 may be turned on and the fourth transistor 524 may be turned off. Thus, the first output node ON11 may change to a low logic level, and the second output node ON12 may change to a high logic level as the sixth transistor 526 is turned on. As the sixth transistor 526 and the seventh transistor 527 are maintained in the turn-on state, the first output node ON11 may be maintained at a low logic level and the second output node ON12 may be maintained at a high logic level. The first sampling signal SH1 having a low logic level may be output through the first output node ON11.

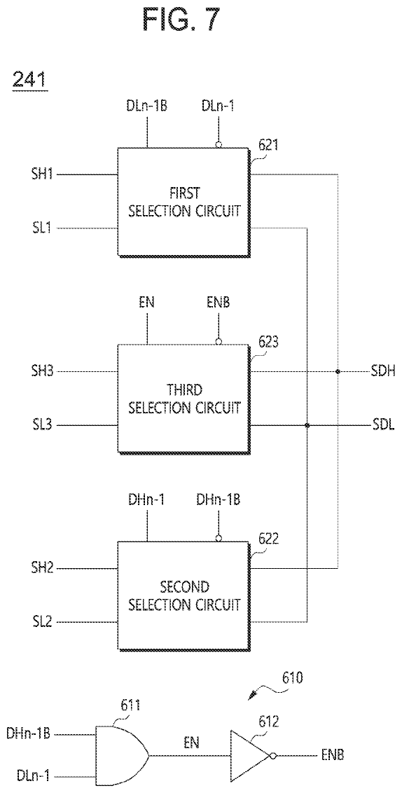

FIG. 7 is a block diagram showing a configuration of the multiplexer 241 shown in FIG. 2. The multiplexer 241 may include a selection signal generation circuit 610, a first selection circuit 621, a second selection circuit 622, and a third selection circuit 623. The selection signal generation circuit 610 may receive an inversion signal of the most significant bit DHn-1B of the n-1th reception symbol and the least significant bit DLn-1 of the n-1th reception symbol. The selection signal generation circuit 610 may generate an enable signal EN and a complementary enable signal ENB by gating the inversion signal of the most significant bit DHn-1B and the least significant bit DLn-1. The selection signal generation circuit 610 may generate the enable signal EN having a high logic level and the complementary enable signal ENB having a low logic level when the most significant bit DHn-1 is 0 and the least significant bit DLn-1 is 1. When the most significant bit DHn-1 is 1 or the least significant bit DLn-1 is 0, the selection signal generation circuit 610 may generate the enable signal EN having a low logic level and the complementary enable signal ENB having a high logic level. The selection signal generation circuit 610 may include an AND gate 611 and an inverter 612. The AND gate 611 may receive the inversion signal of the most significant bit DHn-1B and the least significant bit DLn-1 and output the enable signal EN. The inverter 612 may receive the enable signal EN, invert the enable signal EN, and generate the complementary enable signal ENB.

The first selection circuit 621 may receive the first sampling signal pair SH1, SL1 and the least significant bit DLn-1 of the n-1th reception symbol. When the least significant bit DLn-1 is zero, the first selection circuit 621 may be activated to output the first sampling signal pair SH1, SL1 as the selected sampling signal pair SDH, SDL. The first selection circuit 621 may output the first sampling signal SH1 as the first selected sampling signal SDH, and the second sampling signal SL1 as the second selected sampling signal SDL. The second selection circuit 622 may receive the second sampling signal pair SH2, SL2 and the most significant bit DHn-1 of the n-1th reception symbol. When the most significant bit DHn-1 is 1, the second selection circuit 622 may be activated to output the second sampling signal pair SH2, SL2 as the selected sampling signal pair SDH, SDL. The second selection circuit 622 may output the third sampling signal SH2 as the first selected sampling signal SDH, and the fourth sampling signal SL2 as the second selected sampling signal SDL. The third selection circuit 623 may receive the third sampling signal pair SH3, SL3, the enable signal EN, and the complementary enable signal ENB. The third selection circuit 623 may output the third sampling signal pair SH3, SL3 as the selected sampling signal pair SDH, SDL when the enable signal EN is at a high logic level and the complementary enable signal ENB is at a low logic level. The third selection circuit 623 may output the fifth sampling signal SH3 as the first selected sampling signal SDH, and the sixth sampling signal SL3 as the second selected sampling signal SDL.

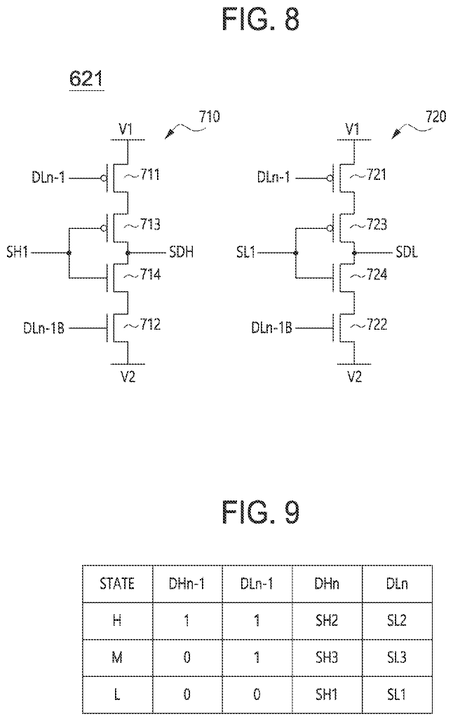

FIG. 8 is a diagram illustrating a configuration of the first selection circuit 621 shown in FIG. 7. Referring to FIG. 8, the first selection circuit 621 may include a first tri-state inverter 710 and a second tri-state inverter 720. The first tri-state inverter 710 may include a first transistor 711, a second transistor 712, a third transistor 713, and a fourth transistor 714. The first transistor 711 and the third transistor 713 may be P-channel MOS transistors, and the second transistor 712 and the fourth transistor 714 may be N-channel MOS transistors. A gate of the first transistor 711 may receive the least significant bit DLn-1 of the n-1th reception symbol, and a source of the first transistor 711 may be coupled with the terminal to which the first power supply voltage V1 is supplied. A gate of the second transistor 712 may receive an inversion signal of the least significant bit DLn-1B, and a source of the second transistor 712 may be coupled with the terminal to which the second power supply voltage V2 is supplied. A gate of the third transistor 713 may receive the first sampling signal SH1, and a source of the third transistor 713 may be coupled with a drain of the first transistor 711. A gate of the fourth transistor 714 may receive the first sampling signal SH1, a drain of the fourth transistor 714 may be coupled to a drain of the third transistor 713, and a source of the fourth transistor 714 may be coupled to a drain of the second transistor 712. The first selected sampling signal SDH may be output from the drains of the third and fourth transistors 713, 714.

The second tri-state inverter 720 may include a fifth transistor 721, a sixth transistor 722, a seventh transistor 723, and an eighth transistor 724. The fifth transistor 721 and the seventh transistor 723 may be P-channel MOS transistors, and the sixth transistor 722 and the eighth transistor 724 may be N-channel MOS transistors. A gate of the fifth transistor 721 may receive the least significant bit DLn-1 of the n-1th reception symbol, and a source of the fifth transistor 721 may be coupled with the terminal to which the first power supply voltage V1 is supplied. A gate of the sixth transistor 722 may receive the inversion signal of the least significant bit DLn-1B, and a source of the sixth transistor 722 may be coupled with the terminal to which the second power supply voltage V2 is supplied. A gate of the seventh transistor 723 may receive the second sampling signal SL1, and a source of the seventh transistor 723 may be coupled with a drain of the fifth transistor 721. A gate of the eighth transistor 724 may receive the second sampling signal SL1, a drain of the eighth transistor 724 is coupled to a drain of the seventh transistor 723, and a source of the eighth transistor 724 may be coupled to a drain of the sixth transistor 722. The second selected sampling signal SDL may be output from the drains of the seventh and eighth transistors 723, 724. The second selection circuit 622 and the third selection circuit 623 may have substantially the same structure as the first selection circuit 621, except for input signals and output signals.

FIG. 9 is a table illustrating an operation of the receiver circuit 200 according to an embodiment. Referring to FIG. 1 through FIG. 9, the operation of the receiver circuit 200 according to an embodiment will be described as follows. The buffer circuit 210 may receive the multi-level signal MS, and differentially amplify the multi-level signal MS and the common mode voltage VCM to generate the input signal IN and the complementary input signal INB. The first summing circuit 221 may lower a voltage level of the complementary input signal INB to generate the first compensation signal I1 and the first complementary compensation signal I1B. The second summing circuit 222 may lower a voltage level of the input signal IN to generate the second compensation signal I2 and the second complementary compensation signal I2B. The averaging circuit 223 may average the first compensation signal I1 and the second compensation signal I2 to generate the third compensation signal I3, and may average the first complementary compensation signal I1B and the second complementary compensation signal I2B to generate the third complementary compensation signal I3B. The first sense amplifier 231 may generate the first sampling signal SH1 and the second sampling signal SL1 by comparing voltage levels of the first compensation signal I1, the first complementary compensation signal I1B, the first reference voltage VREFH, and the second reference voltage VREFL. The second sense amplifier 232 may generate the third sampling signal SH2 and the fourth sampling signal SL2 by comparing voltage levels of the second compensation signal I2, the second complementary compensation signal I2B, the first reference voltage VREFH, and the second reference voltage VREFL. The third sense amplifier 233 may generate the fifth sampling signal SH3 and the sixth sampling signal SL3 by comparing voltage levels of the third compensation signal I3, the third complementary compensation signal I3B, the first reference voltage VREFH, and the second reference voltage VREFL.

When a state of the n-1th reception symbol DHn-1, DLn-1 was the first state H, the most significant bit DHn-1 and the least significant bit DLn-1 of the n-1th reception symbol may be 1. Accordingly, the multiplexer 241 may output the third sampling signal SH2 as the first selected sampling signal SDH, and the fourth sampling signal SL2 as the second selected sampling signal SDL. The latch circuit 242 may output the first selected sampling signal SDH as the most significant bit DHn of the nth reception symbol, and may output the second selected sampling signal SDL as the least significant bit DLn of the nth reception symbol. When a state of the n-1th reception symbol DHn-1, DLn-1 was the third state L, the most significant bit DHn-1 and the least significant bit DLn-1 of the n-1th reception symbol may be zero. Accordingly, the multiplexer 241 may output the first sampling signal SH1 as the first selected sampling signal SDH, and the second sampling signal SL1 as the second selected sampling signal SDL. The latch circuit 242 may output the first selected sampling signal SDH as the most significant bit DHn of the nth reception symbol, and may output the second selected sampling signal SDL as the least significant bit DLn of the nth reception symbol. When a state of the n-1th reception symbol DHn-1, DLn-1 was the second state M, the most significant bit DHn-1 of the n-1th reception symbol may be 0, and the least significant bit DLn-1 of the n-1th reception symbol may be 1. Accordingly, the selection signal generation circuit 610 may generate the enable signal EN having a high logic level, and the multiplexer 241 may output the fifth sampling signal SH3 as the first selected sampling signal SDH, and the sixth sampling signal SL3 as the second selected sampling signal SDL. The latch circuit 242 may output the first selected sampling signal SDH as the most significant bit DHn of the nth reception symbol, and the second selected sampling signal SDL as the least significant bit DLn of the nth reception symbol.

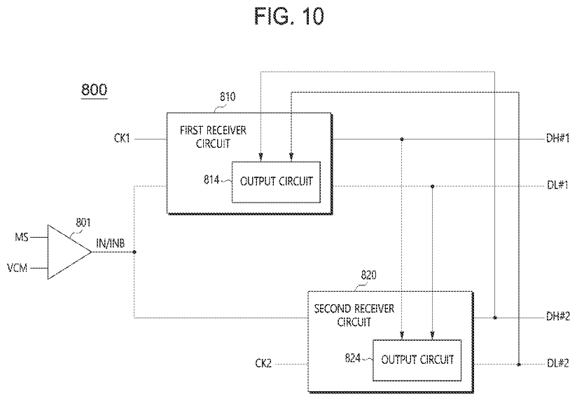

FIG. 10 is a diagram illustrating a configuration of a semiconductor apparatus 800 according to an embodiment. Referring to FIG. 10, the semiconductor apparatus 800 may have two receiver circuits and may receive a multi-level signal MS using two phase clock signals. The semiconductor apparatus 800 may include a buffer circuit 801, a first receiver circuit 810, and a second receiver circuit 820. The buffer circuit 801 may receive the multi-level signal MS, and generate an input signal pair IN, INB based on the multi-level signal MS. The buffer circuit 801 may further receive a common mode voltage VCM. The buffer circuit 801 may differentially amplify the multi-level signal MS and the common mode voltage VCM to generate the input signal pair IN, INB. The buffer circuit 210 illustrated in FIG. 2 may be applied as the buffer circuit 801.

The first and second receiver circuits 810, 820 may receive the input signal pair IN, INB in common. The first receiver circuit 810 may receive a first phase clock signal CK1, and the second receiver circuit 820 may receive a second phase clock signal CK2. The second phase clock signal CK2 may have a lagged phase relative to a phase of the first phase clock signal CK1, and may have a phase opposite to the first phase clock signal CK1 (i.e., a phase difference of 180 degrees). The first receiver circuit 810 may generate the most significant bit DH #1 and the least significant bit DL #1 of a first reception symbol from the input signal Pair IN, INB in synchronization with the first phase clock signal CK1. The second receiver circuit 820 may generate the most significant bit DH #2 and the least significant bit DL #2 of a second reception symbol from the input signal pair IN, INB in synchronization with the second phase clock signal CK2. The receiver circuit 200 illustrated in FIG. 2 may be applied as the first and second receiver circuits 810, 820, respectively. Each of the first and second receiver circuits 810, 820 may include the configurations of the receiver circuit 200 except for the buffer circuit 210. The first receiver circuit 810 may include an output circuit 814, and the second receiver circuit 820 may include an output circuit 824. The output circuits 814, 824 may each have a configuration corresponding to the output circuit 240 illustrated in FIG. 2.

The output circuit 814 of the first receiver circuit 810 may receive the second reception symbol DH #2, DL #2 from the second receiver circuit 820. The output circuit 814 may select one of sampling signal pairs based on the most significant bit DH #2 and least significant bit DL #2 of the second reception symbol to generate the first reception symbol DH #1, DL #1. Although not shown, an amplification circuit of the first receiver circuit 810 may operate in synchronization with the first phase clock signal CK1, and the output circuit 814 of the first receiver circuit 810 may operate in synchronization with the second phase clock signal CK2. The output circuit 824 of the second receiver circuit 820 may receive the first reception symbol DH #1, DL #1 from the first receiver circuit 810. The output circuit 824 may select one of sampling signal pairs based on the most significant bit DH #1 and least significant bit DL #1 of the first reception symbol to generate the second reception symbol DH #2, DL #2. Although not shown, an amplification circuit of the second receiver circuit 820 may operate in synchronization with the second phase clock signal CK2, and the output circuit 824 of the second receiver circuit 820 may operate in synchronization with the first phase clock signal CK1.

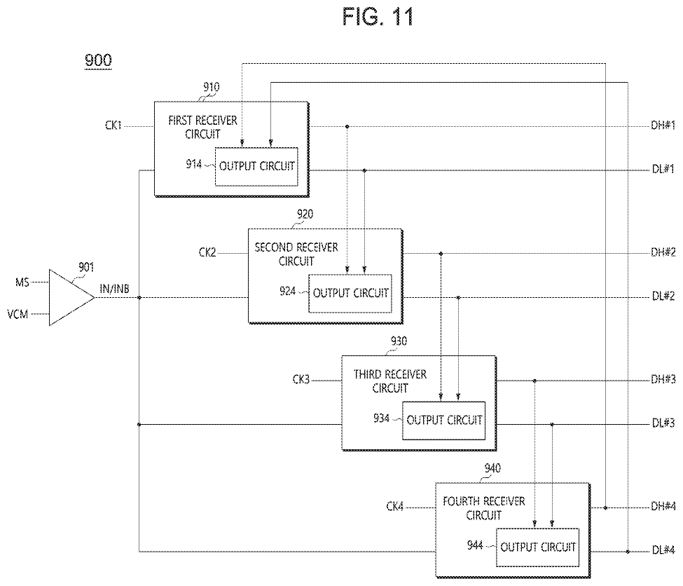

FIG. 11 is a diagram illustrating a configuration of a semiconductor apparatus 900 according to an embodiment. Referring to FIG. 11, the semiconductor apparatus 900 may have four receiver circuits and receive a multi-level signal MS using four phase clock signals. The semiconductor apparatus 900 may include a buffer circuit 901, a first receiver circuit 910, a second receiver circuit 920, a third receiver circuit 930, and a fourth receiver circuit 940. The buffer circuit 901 may receive the multi-level signal MS, and generate an input signal pair IN, INB based on the multi-level signal MS. The buffer circuit 901 may further receive a common mode voltage VCM. The buffer circuit 901 may differentially amplify the multi-level signal MS and the common mode voltage VCM to generate the input signal pair IN, INB. The buffer circuit 210 illustrated in FIG. 2 may be applied as the buffer circuit 901.

The first to fourth receiver circuits 910, 920, 930, 940 may receive the input signal pair IN, INB in common. The first receiver circuit 910 may receive a first phase clock signal CK1, and the second receiver circuit 920 may receive a second phase clock signal CK2. The third receiver circuit 930 may receive a third phase clock signal CK3, and the fourth receiver circuit 940 may receive a fourth phase clock signal CK4. The first to fourth phase clock signals CK1, CK2, CK3, CK4 may have a phase difference of 90 degrees sequentially. The first phase clock signal CK1 may have a phase advanced relative to a phase of the second phase clock signal CK2, and the second phase clock signal CK2 may have a phase advanced relative to a phase of the third phase clock signal CK3. The third phase clock signal CK3 may have a phase advanced relative to a phase of the fourth phase clock signal CK4, and the fourth phase clock signal CK4 may have a phase advanced relative to a phase of the first phase clock signal CK1. The first receiver circuit 910 may generate the most significant bit DH #1 and the least significant bit DL #1 of a first reception symbol from the input signal pair IN, INB in synchronization with the first phase clock signal CK1. The second receiver circuit 920 may generate the most significant bit DH #2 and the least significant bit DL #2 of a second reception symbol from the input signal pair IN, INB in synchronization with the second phase clock signal CK2. The third receiver circuit 930 may generate the most significant bit DH #3 and the least significant bit DL #3 of a third reception symbol from the input signal pair IN, INB in synchronization with the third phase clock signal CK3. The fourth receiver circuit 940 may generate the most significant bit DH #4 and the least significant bit DL #4 of a fourth reception symbol from the input signal pair IN, INB in synchronization with the fourth phase clock signal CK4. The receiver circuit 200 illustrated in FIG. 2 may be applied as the first to fourth receiver circuits 910, 920, 930, 940, respectively. Each of the first to fourth receiver circuits 910, 920, 930, 940 may include the configurations of the receiver circuit 200 except for the buffer circuit 210. The first receiver circuit 910 may include an output circuit 914, and the second receiver circuit 920 may include an output circuit 924. The third receiver circuit 930 may include an output circuit 934, and the fourth receiver circuit 940 may include an output circuit 944. Each of the output circuits 914, 924, 934, 944 may have a configuration corresponding to the output circuit 240 illustrated in FIG. 2.

The output circuit 914 of the first receiver circuit 910 may receive the fourth reception symbol DH #4, DL #4 from the fourth receiver circuit 940. The output circuit 914 may select one of sampling signal pairs based on the most significant bit DH #4 and least significant bit DL #4 of the fourth reception symbol to generate the first reception symbol DH #1, DL #1. Although not shown, an amplification circuit of the first receiver circuit 910 may operate in synchronization with the first phase clock signal CK1, and the output circuit 914 of the first receiver circuit 910 may operate in synchronization with the second phase clock signal CK2. The output circuit 924 of the second receiver circuit 920 may receive the first reception symbol DH #1, DL #1 from the first receiver circuit 910. The output circuit 924 may select one of sampling signal pairs based on the most significant bit DH #1 and least significant bit DL #1 of the first reception symbol to generate the second reception symbol DH #2, DL #2. Although not shown, an amplification circuit of the second receiver circuit 920 may operate in synchronization with the second phase clock signal CK2, and the output circuit 924 of the second receiver circuit 920 may operate in synchronization with the third phase clock signal CK3. The output circuit 934 of the third receiver circuit 930 may receive the second reception symbol DH #2, DL #2 from the second receiver circuit 920. The output circuit 934 may select one of sampling signal pairs based on the most significant bit DH #2 and least significant bit DL #2 of the second reception symbol to generate the third reception symbol DH #3, DL #3. Although not shown, an amplification circuit of the third receiver circuit 930 may operate in synchronization with the third phase clock signal CK3, and the output circuit 934 of the third receiver circuit 930 may operate in synchronization with the fourth phase clock signal CK4. The output circuit 944 of the fourth receiver circuit 940 may receive the third reception symbol DH #3, DL #3 from the third receiver circuit 930. The output circuit 944 may select one of sampling signal pairs based on the most significant bit DH #3 and least significant bit DL #3 of the third reception symbol to generate the fourth reception symbol DH #4, DL #4. Although not shown, an amplification circuit of the fourth receiver circuit 940 may operate in synchronization with the fourth phase clock signal CK4, and the output circuit 944 of the fourth receiver circuit 940 may operate in synchronization with the first phase clock signal CK1.

A person skilled in the art to which the present disclosure pertains can understand that the present disclosure may be carried out in other specific forms without changing its technical spirit or essential features. Therefore, it should be understood that the embodiments described above are illustrative in all aspects, not limitative. The scope of the present disclosure is defined by the claims to be described below rather than the detailed description, and it should be construed that the meaning and scope of the claims and all changes or modified forms derived from the equivalent concept thereof are included in the scope of the present disclosure.

What is claimed is:

1. A receiver circuit comprising:
a first summing circuit configured to receive an input signal pair and equalize the input signal pair with a first offset to generate a first compensation signal pair;
a second summing circuit configured to receive the input signal pair and equalize the input signal pair with a second offset to generate a second compensation signal pair;
an averaging circuit configured to receive the first compensation signal pair and the second compensation signal pair to average voltage levels of the first compensation signal pair and the second compensation signal pair to generate a third compensation signal pair;
a sampling circuit configured to receive the first compensation signal pair, the second compensation signal pair, and the third compensation signal pair to compare the first compensation signal pair, the second compensation signal pair, and the third compensation signal pair with a first reference voltage and a second reference voltage to generate a first sampling signal pair, a second sampling signal pair, and a third sampling signal pair, respectively; and
an output circuit configured to generate an nth reception symbol from one sampling signal pair among the first to third sampling signal pairs based on an n-1th reception symbol,
wherein the n is an integer of 2 or more.

2. The receiver circuit of claim 1, wherein the input signal pair includes an input signal and a complementary input signal, and the first compensation signal pair includes a first compensation signal and a first complementary compensation signal, and
wherein the first summing circuit is configured to generate the first compensation signal having a voltage level substantially equal to a voltage level of the input signal, and the first complementary compensation signal having a voltage level lower than a voltage level of the complementary input signal.

3. The receiver circuit of claim 2, wherein the second compensation signal pair includes a second compensation signal and a second complementary compensation signal, and
wherein the second summing circuit is configured to generate the second compensation signal having a voltage level lower than a voltage level of the input signal, and the second complementary compensation signal having a voltage level substantially equal to a voltage level of the complementary input signal.

4. The receiver circuit of claim 3, wherein the third compensation signal pair includes a third compensation signal and a third complementary compensation signal, and
wherein the averaging circuit is configured to generate the third compensation signal having a voltage level corresponding to substantially a middle between voltage levels of the first and second compensation signals, and the third complementary compensation signal having a voltage level corresponding to substantially a middle between voltage levels of the first and second complementary compensation signals.

5. The receiver circuit of claim 1, wherein the averaging circuit comprises:
a first load circuit; and
a second load circuit,
wherein one end of the first load circuit receives the first compensation signal pair, and the other end of the first load circuit is coupled to a node from which the third compensation signal pair is output, and
wherein one end of the second load circuit receives the second compensation signal pair, and the other end of the second load circuit is coupled to the node from which the third compensation signal pair is output.

6. The receiver circuit of claim 1, wherein the sampling circuit comprises:
a first sense amplifier configured to sense and amplify the first compensation signal pair, the first reference voltage, and the second reference voltage to generate the first sampling signal pair;
a second sense amplifier configured to sense and amplify the second compensation signal pair, the first reference voltage, and the second reference voltage to generate the second sampling signal pair; and
a third sense amplifier configured to sense and amplify the third compensation signal pair, the first reference voltage, and the second reference voltage to generate the third sampling signal pair.

7. The receiver circuit of claim 1, wherein the output circuit is configured to output the second sampling signal pair as the nth reception symbol when the n-1th reception symbol is in a first state, configured to output the third sampling signal pair as the nth reception symbol when the n-1th reception symbol is in a second state, and configured to output the first sampling signal pair as the nth reception symbol when the n-1th reception symbol is in a third state.

8. The receiver circuit of claim 1, wherein the output circuit comprises:
a multiplexer configured to output one of the first to third sampling signal pairs as a selected sampling signal pair based on the n-1th reception symbol; and
a latch circuit configured to latch the selected sampling signal pair to generate the nth reception symbol.

9. A semiconductor apparatus comprising:
a first receiver circuit configured to receive an input signal pair, and configured to generate a first reception symbol from the input signal pair in synchronization with a first phase clock signal; and
a second receiver circuit configured to receive the input signal pair, and configured to generate a second reception symbol from the input signal pair in synchronization with a second phase clock signal,
wherein the first receiver circuit comprises:
a compensation signal generation circuit configured to equalize the first input signal pair with a first offset to generate a first compensation signal pair, configured to equalize the input signal pair with a second offset to generate a second compensation signal pair, and configured to average voltage levels of the first compensation signal pair and the second compensation signal pair to generate a third compensation signal pair;
a sampling circuit configured to compare the first compensation signal pair, the second compensation signal pair, and the third compensation signal pair with a first reference voltage and a second reference voltage to generate a first sampling signal pair, a second sampling signal pair, and a third sampling signal pair, respectively in synchronization with the first phase clock signal; and
an output circuit configured to select one sampling signal pair among the first to third sampling signal pairs based on the second reception symbol to generate a selected sampling signal pair, and configured to generate the selected sampling signal pair as the first reception symbol in synchronization with the first phase clock signal.

10. The semiconductor apparatus of claim 9, wherein the compensation signal generation circuit comprises:
a first summing circuit configured to equalize the input signal pair with the first offset to generate the first compensation signal pair;
a second summing circuit configured to equalize the input signal pair with the second offset to generate the second compensation signal pair; and
an averaging circuit configured to average the voltage levels of the first compensation signal pair and the second compensation signal pair to generate the third compensation signal pair.

11. The semiconductor apparatus of claim 10, wherein the input signal pair includes an input signal and a complementary input signal, and the first compensation signal pair includes a first compensation signal and a first complementary compensation signal, and
wherein the first summing circuit is configured to generate the first compensation signal having a voltage level substantially equal to a voltage level of the input signal, and the first complementary compensation signal having a voltage level lower than a voltage level of the complementary input signal.

12. The semiconductor apparatus of claim 11, wherein the second compensation signal pair includes a second compensation signal and a second complementary compensation signal, and
wherein the second summing circuit is configured to generate the second compensation signal having a voltage level lower than a voltage level of the input signal, and the second complementary compensation signal having a voltage level substantially equal to a voltage level of the complementary input signal.

13. The semiconductor apparatus of claim 12, wherein the third compensation signal pair includes a third compensation signal and a third complementary compensation signal, and
wherein the averaging circuit is configured to generate the third compensation signal having a voltage level corresponding to substantially a middle between voltage levels of the first and second compensation signals, and the third complementary compensation signal having a voltage level corresponding to substantially a middle between voltage levels of the first and second complementary compensation signals.

14. The semiconductor apparatus of claim 10, wherein the averaging circuit comprises:
a first load circuit; and
a second load circuit,
wherein one end of the first load circuit receives the first compensation signal pair, and the other end of the first load circuit is coupled to a node from which the third compensation signal pair is output, and
wherein one end of the second load circuit receives the second compensation signal pair, and the other end of the second load circuit is coupled to the node from which the third compensation signal pair is output.

15. The semiconductor apparatus of claim 9, wherein the sampling circuit comprises:
a first sense amplifier configured to sense and amplify the first compensation signal pair, the first reference voltage, and the second reference voltage to generate the first sampling signal pair in synchronization with the first phase clock signal;
a second sense amplifier configured to sense and amplify the second compensation signal pair, the first reference voltage, and the second reference voltage to generate the second sampling signal pair in synchronization with the first phase clock signal; and
a third sense amplifier configured to sense and amplify the third compensation signal pair, the first reference voltage, and the second reference voltage to generate the third sampling signal pair in synchronization with the first phase clock signal.

16. The semiconductor apparatus of claim 9, wherein the output circuit is configured to output the second sampling signal pair as the first reception symbol when the second reception symbol is in a first state, configured to output the third sampling signal pair as the first reception symbol when the second reception symbol is in a second state, and configured to output the first sampling signal pair as the first reception symbol when the second reception symbol is in a third state.

17. The semiconductor apparatus of claim 9, wherein the output circuit comprises:
a multiplexer configured to output one sampling signal pair among the first to third sampling signal pairs as the selected sampling signal pair based on the second reception symbol; and
a latch circuit configured to latch the selected sampling signal pair to generate the first reception symbol in synchronization with the first phase clock signal.

18. The semiconductor apparatus of claim 9, wherein the second receiver circuit is configured to further receive the first reception symbol, and configured to generate the second reception symbol from the input signal pair based on the first reception symbol.
